(19) United States
(12) Patent Application Publication
(10) Pub. No.: US 2008/0132030 A1
(43) Pub. Date: Jun. 5, 2008

(54) METHOD OF MANUFACTURING SEMICONDUCTOR DEVICE

(75) Inventors: Il-Young YOON, Gyeonggi-do (KR); Dong-Suk SHIN, Gyeonggi-do (KR); Jae-Ouk CHOO, Gyeonggi-do (KR); Ja-Eung KOO, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/950,306

(22) Filed: Dec. 4, 2007

(30) Foreign Application Priority Data
Dec. 5, 2006 (KR) 2006-122264

(51) Int. Cl. H01L 21/762

(52) U.S. Cl. 438/435; 257/E21.546

(57) ABSTRACT

After sequentially forming an insulating layer and a capping dielectric layer having a higher density than the insulating layer, a chemical mechanical polishing (CMP) process is performed to prevent scratch from being formed on the surface of the insulating layer at the early stage of the CMP process. Thus, a semiconductor device with improved reliability is achieved.

### CROSS-REFERENCE TO RELATED APPLICATIONS

This patent application claims the benefit of foreign priority under 35 U.S.C. § 119 to Korean Patent Application No. 2006-122264 filed on Dec. 5, 2006, the entire contents of which are hereby incorporated by reference.

### BACKGROUND

1. Field of Invention

Embodiments described herein relate to methods of manufacturing semiconductor devices. More specifically, embodiments described herein relate to a method of manufacturing a semiconductor device with improved reliability.

2. Description of the Related Art

As the integration of semiconductor devices has been highly increased, shallow trench isolation (STI) processes have been widely used to form device isolation region of the semiconductor devices. Generally, an STI process includes etching a semiconductor substrate to form a trench, forming an oxide layer to fill the trench and planarizing the oxide layer. The oxide layer may be formed of low temperature high density plasma (LT-HDP) oxide having a relatively high gap-fill property to fill a narrow trench.

The planarization of the oxide layer may be performed by means of an etchback process or a chemical mechanical polishing (CMP) process. CMP processes are widely used due to their simplicity and high reliability. The CMP process may enable a planarization process to be performed without addition of a masking process or a coating process.

In the CMP process, a polishing pad attached on the surface of a polishing table rotating or eccentrically moving presses against the oxide layer of the semiconductor substrate to polish and planarize the oxide layer. The CMP process includes feeding slurry onto the oxide layer. Thus, the oxide layer is planarized chemically and mechanically.

At the early stage of the CMP process, the polishing pad is provided to polish the oxide layer at a high pressure. Because the surface of the oxide layer is not hydrated, the possibility of scratches caused by physical friction is relatively high. If a film density is low or if a surface roughness is high, the frequency of scratches may increase and the scratches may extend as the CMP process is performed.

A scratch formed on the surface of a semiconductor device will now be described below with reference to FIG. 1.

As shown in FIG. 1, a scratch 101 may easily be formed on the surface of an LT-HDP oxide layer having a superior gap-fill property and low density due to a slurry-containing abrasive. The scratch 101 may have a depth of 100 nanometers or more and a width in the range of 0.1 to 1 micrometer. If residues from a conductive material exist at the scratch 101, conductive patterns such as a gate electrode to be isolated by a device isolation region 110 may be shorted. Accordingly, the scratch 101 may be a serious defect of a semiconductor device. Thus, reliability of the semiconductor device may be degraded.

### SUMMARY

One exemplary embodiment described herein can be generally characterized as a method of manufacturing a semiconductor device that includes forming a trench in a semiconductor substrate, forming an insulating layer filling the trench, and forming a capping dielectric layer on the insulating layer. The capping dielectric layer may have a higher density than the insulating layer. Subsequently, the capping dielectric layer and the insulating layer may be planarized using a chemical mechanical polishing (CMP) process to form a planarized insulating layer.

Another exemplary embodiment described herein can be generally characterized as a method of manufacturing a semiconductor device that includes forming an insulating layer over a substrate such that an upper surface of the insulating layer has a step difference between an upper region of the upper surface and a lower region of the upper surface. A capping dielectric layer may be formed on the upper surface of the insulating layer. The capping dielectric layer may have a higher density than the insulating layer. Subsequently, the capping dielectric layer and the insulating layer may be planarized using a chemical mechanical polishing (CMP) process to form a planarized insulating layer having a substantially planar upper surface.

### BRIEF DESCRIPTION OF THE DRAWINGS

These and other embodiments of the present invention will become more readily apparent when the following detailed description is taken in conjunction with the accompanying drawings, in which:

FIG. 1 is a scanning electron microscope (SEM) photo of a scratch-formed plane surface of a conventional semiconductor device;

FIGS. 2A through 2E are cross-sectional views illustrating an exemplary method of manufacturing a semiconductor device according to one embodiment;

FIGS. 3A through 3C are cross-sectional views illustrating an exemplary method of manufacturing a semiconductor device according to another embodiment; and

FIG. 4 shows plan views illustrating a relative reduction in frequency of scratches formed on semiconductor devices according to one embodiment.

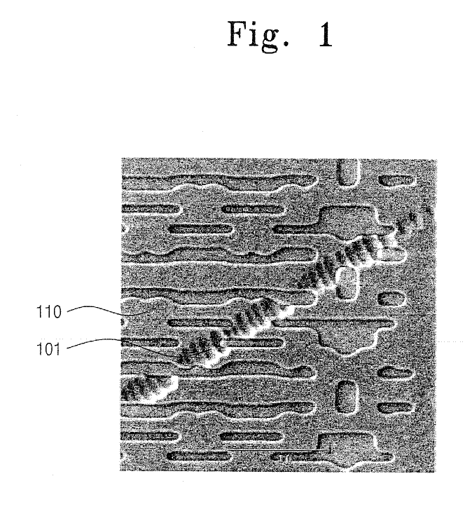

### DETAILED DESCRIPTION

Exemplary embodiments of the present invention will be described more fully hereinafter with reference to the accompanying drawings. These embodiments, however, may be realized in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like numbers refer to like elements throughout.

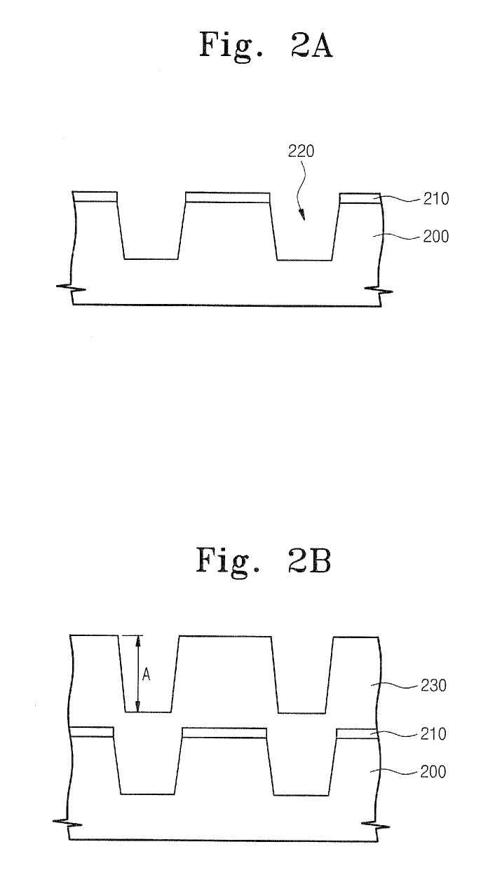

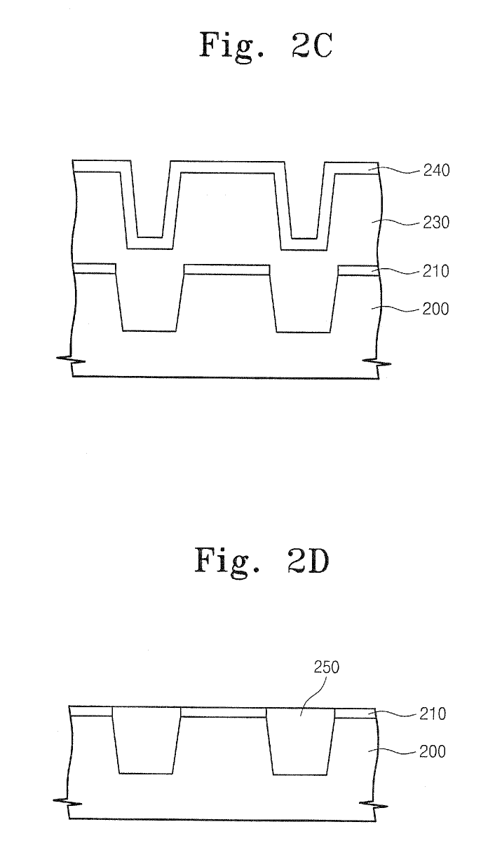

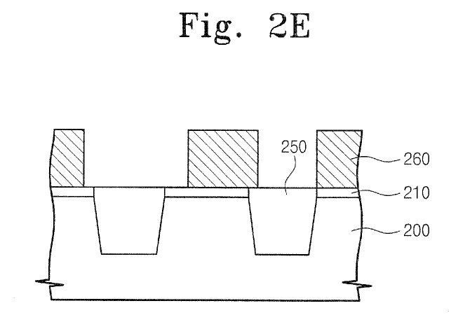

An exemplary method of manufacturing a semiconductor device according to one embodiment will be described with reference to FIGS. 2A through 2E.

Referring to FIG. 2A, a portion of a semiconductor substrate 200 is etched to form a trench 220. The trench 220 may be formed by means of a conventional etch process.

For example, an etch-stop layer 210 is formed on the semiconductor substrate 200. The etch-stop layer 210 may be formed of oxide or nitride. A mask layer (not shown) may be formed on the etch-stop layer 210. The mask layer may be a photoresist layer. The mask layer may be patterned by means of a conventional photolithography process to form a mask pattern (not shown). Using the mask pattern as a mask, the semiconductor substrate 200 may be etched to form a trench 220. The mask pattern may then be removed. In the trench 220, a diffusion barrier layer (not shown) may be formed to prevent the diffusion resulting from a thermal process.

Referring to FIG. 2B, an insulating layer 230 is formed on the semiconductor substrate 200 to fill the trench 220. In one embodiment, the insulating layer 230 may include an oxide. The insulating layer 230 may, for example, include a material having a gap-fill property suitable for substantially filling the trench 220. For example, the insulating layer 230 may include a material such as boron phosphorus silicate glass (BPSG), phosphorus silicate glass (PSG), a spin-on-glass (SOG) material, a semi-atmospheric chemical vapor deposition (SACVD) material, a high aspect ratio process (HARP) material, a low temperature high density plasma (LT-HDP) material, or the like or a combination thereof.

In one embodiment, the insulating layer 230 may be provided as an LT-HDP layer. In such an embodiment, the insulating layer 230 may not be fully formed below a temperature of about 100 degrees centigrade and the gap-fill property of the insulating layer 230 decreases over a temperature of about 400 degrees centigrade. Therefore, the insulating layer 230 may be formed at a process temperature in the range of about 100 degrees centigrade to about 400 degrees centigrade.

The insulating layer 230 is formed to have a height greater than a depth of the trench 220, so as to fill the trench 220. The insulating layer 230 is formed along the profile of the semiconductor substrate 200 and the trench 220. As a result, the profile of the upper surface of the insulating layer 230 may have a step difference “A” corresponding to the profile of the semiconductor substrate 200 and the trench 220.

Referring to FIG. 2C, a capping dielectric layer 240 is formed on the insulating layer 230.

In one embodiment, the capping dielectric layer 240 has higher density than the insulating layer 230. For example, the capping dielectric layer 240 may include plasma tetraethylorthosilicate (PTEOS) material, a high temperature high density plasma (HT-HDP) material, or the like or a combination thereof.

In one embodiment, the capping dielectric layer 240 may be provided as a HT-HDP layer. A density of the capping dielectric layer 240 is not high enough below a temperature of about 400 degrees centigrade and does not increase over a temperature of about 900 degrees centigrade. Therefore, the capping dielectric layer 240 can be formed at a process temperature in the range of about 400 degrees centigrade to about 900 degrees centigrade.

If the thickness of the capping dielectric layer 240 is less than about 1/20 the thickness of the insulating layer 230, it may be difficult to prevent the formation of scratches. If the thickness of the capping dielectric layer 240 is more than about ⅓ the thickness of the insulating layer 230, the time required for performing a planarization process may be undesirably increased. Accordingly, the thickness of the capping dielectric layer 240 may be about 1/20 to about ⅓ the thickness of the insulating layer 230. In one embodiment, the thickness of the capping dielectric layer 240 may be smaller than that of the insulating layer 230, e.g., about 1/20 to about ⅕ the thickness of the insulating layer 230.

In one embodiment, an additional nitride layer (not shown) may be formed on the capping dielectric layer 240. The additional nitride layer may, for example, include a material such as SiN, SiON, SiCN, or the like or a combination thereof. If the thickness of the additional nitride layer is less than about 1/120 the thickness of the insulating layer 230, it may be difficult to prevent the formation of scratches. If the thickness of the additional nitride layer is more than about 1/12 the thickness of the insulating layer 230, the time required for performing a planarization process may be undesirably increased. Accordingly, the thickness of the additional nitride layer may be about 1/120 to about 1/12 the thickness of the insulating layer 230.

In another embodiment, the capping dielectric layer 240 may include a nitride material such as SiN, SiON, SiCN or the like or a combination thereof. In such an embodiment, the aforementioned additional nitride layer need not be formed. Because the capping dielectric layer 240 includes a nitride material, a hardness of the capping dielectric layer 240 can be improved to prevent the formation of scratch despite a polishing process. The thickness of the capping dielectric layer 240 and the thickness of the additional nitride layer may vary with the conditions of a chemical mechanical polishing (CMP) process to be performed.

Referring to FIG. 2D, the insulating layer 230 is planarized to expose the etch-stop layer by performing a CMP process. Accordingly, the capping dielectric layer 240 is removed and the insulating layer 230 is substantially planarized. As a result, a field oxide layer 250 is formed in the trench 220 to define an active region.

In one embodiment, the condition of the CMP process may be controlled by regulating a polishing pressure and a rotational speed (e.g., of a polishing pad employed during the CMP process). If the polishing pressure is less than about 1 psi, the CMP process may not be adequately performed. If the polishing pressure is more than about 5 psi, scratches may be formed or cracks may be formed. Therefore, the polishing pressure may be in the range of about 1 psi to about 5 psi.

If the rotational speed is less than about 10 rpm, a polishing time may be undesirably increased and the capability of sufficiently planarizing layers may be poor. If the rotational speed is more than about 100 rpm, the apparatus and device may be damaged. Therefore, the rotational speed may be in the range of about 10 rpm to about 100 rpm.

Upon performing a CMP process according to the conditions outlined above, a strong friction force may be applied to the capping dielectric layer 240 during an early stage of the CMP process. Although scratches may be formed on the capping dielectric layer 240, the capping dielectric layer 240 may nevertheless serve to reduce the formation of scratches on underlying layers. Since the capping dielectric layer 240 is removed, the field oxide layer 250 formed by means of the CMP process may have a surface that is free of scratches. In some embodiments, the CMP process conditions described above can be selected to obtain a field oxide layer 250 having a surface that is substantially free of scratches.

Referring to FIG. 2E, a gate electrode 260 is formed on the active region. In one embodiment, the gate electrode 260 may be formed by forming a gate dielectric layer (not shown) on the resultant structure including the active region and forming a polysilicon layer (not shown) on the gate dielectric layer. The polysilicon layer and the gate dielectric layer may then be patterned using a conventional photolithography process to form a gate electrode 260.

In some embodiments, the gate electrode 260 may be formed over the device isolation region (i.e., over the field oxide layer 250) and the active region. Conventionally, if scratches remain in the device isolation region, then adjacent gate electrodes 260 may be shorted with each other. Such electrical shorting is generally not desirable because gate electrode 260 should be electrically isolated from each other by the device isolation region. However, when forming the gate electrode 260, portions of the polysilicon layer can be deposited in scratches and, as a result, will not be fully removed using conventional photolithography processes. Accordingly, adjacent gate electrodes 260 may be electrically connected to each other by the portions of polysilicon remaining in scratches of the device isolation region and a malfunction may occur within a semiconductor device.

According to the embodiments described above, however, scratches are not formed on the surface of the device isolation region (i.e., on the surface of the field oxide layer 250). Thus, the gate electrodes 260 may be fully isolated by the device isolation region. In embodiments where the surface of the field oxide layer 250 is substantially free of scratches, very small scratches may remain. In such an embodiment, however, the polysilicon layer forming the gate electrode 260 may be easily removed because the depth and width of any remaining scratches is very small. Accordingly, the reliability of a semiconductor device is not degraded.

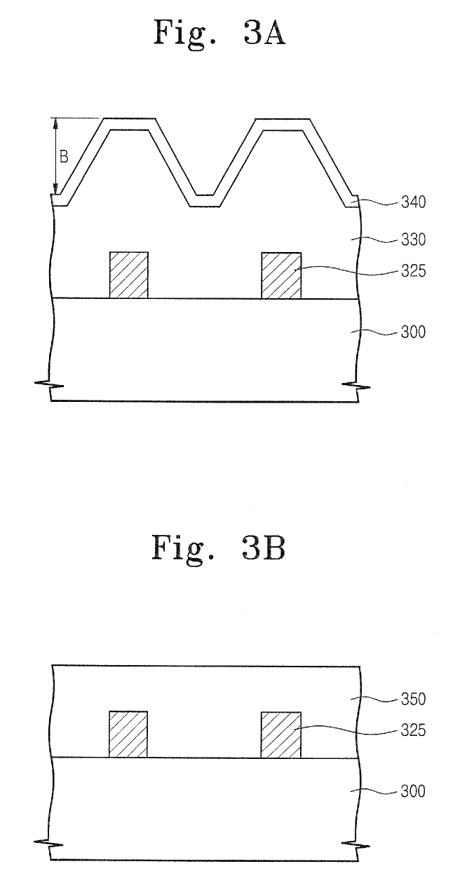

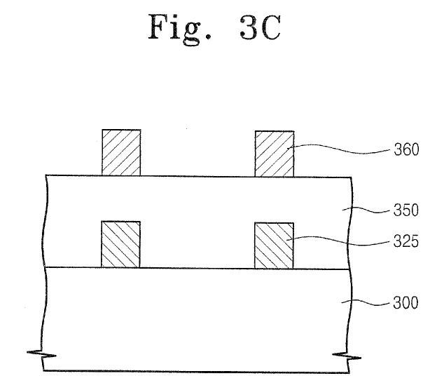

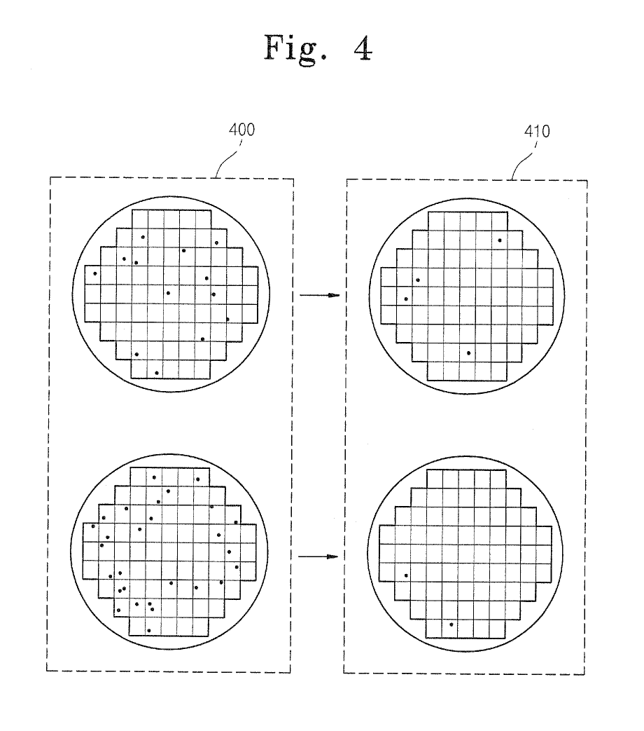

FIGS. 3A through 3C are cross-sectional views illustrating an exemplary method of manufacturing a semiconductor device according to another embodiment.

Referring to FIG. 3A, a semiconductor substrate 300 is provided. The semiconductor substrate 300 may include a device isolation region (not shown) and an active region (not shown) defined by the device isolation region. A first conductive pattern 325 is formed on the active region. The first conductive pattern 325 may, for example, include a gate electrode of a transistor, a metal interconnect, or the like. An insulating layer 330 is formed on the first conductive layer 325. The insulating layer 330 may, for example, include a material having a gap-fill property suitable for substantially filling spaces formed between adjacent first conductive patterns 325. Thus, the insulating layer 330 may be sufficiently formed, even if a critical dimension (CD) of the first conductive pattern 325 decreases while a height of the first conductive pattern 325 increases. In one embodiment, the insulating layer 230 may include an oxide. In another embodiment, the insulating layer 330 may include a material such as boron phosphorus silicate glass (BPSG), phosphorus silicate glass (PSG), a spin-on-glass (SOG) material, a semi-atmospheric chemical vapor deposition (SACVD) material, a high aspect ratio process (HARP) material, a low temperature high density plasma (LT-HDP) material, or the like of a combination thereof.

In one embodiment, the insulating layer 330 may be provided as an LT-HDP layer. In such an embodiment, the insulating layer 330 may not be fully formed below a temperature of about 100 degrees centigrade and the gap-fill property of the insulating layer 330 decreases over a temperature of about 400 degrees centigrade. Therefore, the insulating layer 330 may be formed at a process temperature in the range of about 100 degrees centigrade to about 400 degrees centigrade.

The insulating layer 330 is formed to have a height greater than the first conductive pattern 325. The insulating layer 330 is formed along the profile of the semiconductor substrate 300 and the first conductive pattern 325. As a result, the profile of the insulating layer 330 may have a step difference “B”.

A capping dielectric layer 340 is formed on the insulating layer 330. In one embodiment, the capping dielectric layer 340 may include a material such as plasma tetraethylorthosilicate (PTEOS), high temperature high density plasma (HT-HDP), or the like or a combination thereof.

In one embodiment, the capping dielectric layer 340 may be a plasma tetraethylorthosilicate (PTEOS) layer or high temperature high density plasma (HT-HDP) layer.

In one embodiment, the capping dielectric layer 340 may be provided as a HT-HDP layer. A density of the capping dielectric layer 340 is not high enough below a temperature of about 400 degrees centigrade and does not increase over a temperature of about 900 degrees centigrade. Therefore, the capping dielectric layer 340 can be formed at a process temperature in the range of about 400 degrees centigrade to about 900 degrees centigrade.

If the thickness of the capping dielectric layer 340 is less than about 1/20 the thickness of the insulating layer 330, it may be difficult to prevent the formation of scratches. If the thickness of the capping dielectric layer 340 is more than about ⅓ the thickness of the insulating layer 330, the time required for performing a planarization process may be undesirably increased. Accordingly, the thickness of the capping dielectric layer 340 may be about 1/20 to about ⅓ the thickness of the insulating layer 330. In one embodiment, the thickness of the capping dielectric layer 340 may be smaller than that of the insulating layer 330, e.g., about 1/20 to about ⅕ the thickness of the insulating layer 330.

In one embodiment, an additional nitride layer (not shown) may be formed on the capping dielectric layer 340. The additional nitride layer may, for example, include a material such as SiN, SiON, SiCN, or the like or a combination thereof. If the thickness of the additional nitride layer is less than about 1/120 the thickness of the insulating layer 330, it may be difficult to prevent the formation of scratches. If the thickness of the additional nitride layer is more than about 1/12 the thickness of the insulating layer 330, the time required for performing a planarization process may be undesirably increased. Accordingly, the thickness of the additional nitride layer may be about 1/120 to about 1/12 the thickness of the insulating layer 330.

In another embodiment, the capping dielectric layer 340 may include a nitride material such as SiN, SiON, SiCN or the like or a combination thereof. In such an embodiment, the aforementioned additional nitride layer need not be formed.

The thickness of the capping dielectric layer 340 or the thickness of the additional nitride layer may vary with the conditions of a chemical mechanical polishing (CMP) process to be applied.

Referring to FIG. 3B, a CMP process is performed to planarize the insulating layer 330. As a result, the capping dielectric layer 340 is removed and a first interlayer dielectric 350 is formed.

In one embodiment, the condition of the CMP process may be controlled by regulating a polishing pressure and a rotational speed (e.g., of a polishing pad employed during the CMP process). If the polishing pressure is less than about 1 psi, the CMP process may not be adequately performed. If the polishing pressure is more than about 5 psi, scratches may be formed or cracks may be formed. Therefore, the polishing pressure may be in the range of about 1 psi to about 5 psi.

If the rotational speed is less than about 10 rpm, a polishing time may be undesirably increased and the capability of sufficiently planarizing layers may be poor. If the rotational speed is more than about 100 rpm, the apparatus and device may be damaged. Therefore, the rotational speed may be in the range of about 10 rpm to about 100 rpm.

Referring to FIG. 3C, a second conductive pattern 360 is formed on the first interlayer dielectric 350. In one embodiment, the second conductive pattern 360 (e.g., a bit line) may be formed by forming a conductive layer (not shown) on the first interlayer dielectric 350 and patterning the conductive layer. The second conductive pattern 360 may be connected to a contact (not shown) formed in the first interlayer dielectric 350.

Conventionally, if scratches remain on the surface of the first interlayer dielectric 350, a portion of the conductive layer forming the second conductive pattern 360 may remain in the scratch. If the conductive layer remains, adjacent second conductive patterns 360 may be electrically connected to each other. Such electrical connection between adjacent conductive patterns may cause a malfunction of the semiconductor device. Thus, reliability of the semiconductor device may be degraded.

According to the embodiments described above, however, scratches are not formed on the surface of the first interlayer dielectric 350 due to the capping layer 340. As a result, electrical connections between adjacent second conductive patterns 360 may be prevented. In embodiments where the surface of the first interlayer dielectric 350 is substantially free of scratches, the scratches that remain are very small. In such an embodiment, however, the conductive layer forming the second conductive patterns 360 may be easily removed because depth and width of the remaining scratches is very small.

Characteristics of the LT-HDP layer and the HT-HDP layer will be comparatively described below with reference to TABLE 1.

TABLE 1

| Measuring Target | HT-HDP | | LT-HDP | |
|---|---|---|---|---|
| Wet Etch Rate | 308 | Å | 435 | Å |
| CMP Removal | 2705 | Å | 2850 | Å |
| Rate | | | | |
| Stress | −180 | MPa | −144 | MPa |

To measure a wet etch rate, an etch process using buffered oxide etchant (BOE) was performed for approximately one minute. The CMP process was performed for one minute. The wet etch rate of the LT-HDP layer was approximately 41 percent faster than the wet etch rate of the HT-HDP layer. The CMP removal rate of the LT-HDP layer was approximately 5.4 percent faster than the CMP removal rate of the HT-HDP layer. The stress applied to the LT-HDP was approximately 22 percent higher than the stress applied to the HT-HDP layer.

Because the wet etch rate of the HT-HDP layer is slower than the wet etch rate of the LT-HDP layer, and because the stress applied to the HT-HDP is lower than the stress applied to the LT-HDP, the HT-HDP layer has a high density. In spite of the high density of the HT-HDP layer, CMP time of the HT-HDP layer was not significantly different from that of the LT-HDP layer (wherein the “CMP time” refers to the amount of time required for performing a CMP process). Accordingly, the HT-HDP layer may have a good hardness and may be widely applied to processes without considerable variation of CMP process as compared to conventional processes. As a result, HT-HDP capping dielectric layer may prevent scratch during CMP process while process time for CMP process does not increase.

An example embodiment and a comparative embodiment will now be described below. In the example embodiment, the LT-HDP layer and HT-HDP layer are used as an insulating layer and a capping dielectric layer respectively. In the comparative embodiment, an LT-HDP layer is used as an insulating layer and a capping dielectric layer is not used. The insulating layer and the capping dielectric layer may be formed of other materials mentioned above.

### Example Embodiment

A semiconductor substrate was provided. A silicon nitride layer with a thickness of 800 angstroms was formed on the semiconductor substrate as an etch-stop layer. The etch-stop layer and the semiconductor substrate were partially etched by means of a photolithography process to form a trench. An LT-HDP layer with a thickness of 6,000 angstroms was formed on the semiconductor substrate. Helium gas was used as plasma source gas, a temperature was 350 degrees centigrade, and a power was 3,350 watts. An HT-HDP layer with a thickness of 1,000 angstroms was formed on the LT-HDT layer. Helium gas was used as plasma source gas, a temperature was 600 degrees centigrade, and a power was 2,500 watts. The HT-HDP layer was polished and the LT-HDP layer was planarized by means of a chemical mechanical polishing (CMP) process to form a filling oxide layer in the trench.

### Comparative Embodiment

A semiconductor substrate was provided. A silicon nitride layer with a thickness of 800 angstroms was formed on the semiconductor substrate an etch-stop layer. The etch-stop layer and the semiconductor substrate were partially etched by means of a photolithography process to form a trench. An LT-HDP layer with a thickness of 7,000 angstroms was formed on the semiconductor substrate. Helium gas was used as plasma source gas, a temperature was 350 degrees centigrade, and a power was 3,350 watts. The LT-HDP layer was planarized by means of a chemical mechanical polishing (CMP) process to form a filling oxide layer in the trench.

FIG. 4 illustrates top plan views showing the frequency of scratches formed on a semiconductor device according to an exemplary embodiment and frequency of scratches formed on a semiconductor device according to a comparative embodiment.

Referring to FIG. 4, measuring targets of the comparison embodiment and the embodiment were selected at random in semiconductor manufacturing processes. As compared to the comparative embodiment 400, the frequency of scratches formed on the surface of a filling oxide layer formed in the embodiment 410 was reduced. Although semiconductor devices are formed by means of the same process, the scratch frequencies vary with respective substrates. However, the scratch frequency can be reduced by up to about 60 to about 100 percent.

As exemplarily described above, after forming an insulating layer to fill a trench or over conductive patterns, a thin capping dielectric layer is formed on the insulating layer. The capping dielectric layer has a higher density than the insulating layer. A chemical mechanical polishing (CMP) process is performed from the capping dielectric layer to planarize the insulating layer. Therefore, it is possible to overcome the problem of scratches formed on the surface of the insulating layer at the early stage of the CMP process. In this regard, an insulating layer having an improved surface characteristic is provided without changing the amount of time required for performing a CMP process. As a result, reliability of a semiconductor device is enhanced.

According to some embodiments, a method of manufacturing a semiconductor device includes forming a trench in a semiconductor substrate, forming an insulating layer to fill the trench, forming a capping dielectric layer having a higher density than the insulating layer on the insulating layer, and planarizing the capping dielectric layer and the insulating layer by means of a chemical mechanical polishing (CMP) process to form a planarized insulating layer.

In some embodiments, the insulating layer may have a thickness that is thicker than a depth of the trench and is formed along a profile of the substrate and the trench. The insulating layer may include a low temperature high density plasma (LT-HDP) layer, and the capping dielectric layer includes a high temperature high density plasma (HT-HDP) layer. The insulating layer may be deposited at a temperature in the range of 100 degrees centigrade to 400 degrees centigrade, and the capping dielectric layer may be deposited at a temperature in the range of about 400 degrees centigrade to about 900 degrees centigrade. A thickness of the capping dielectric layer may be about 1/20 to about ⅓ smaller than that of the insulating layer. The CMP process can be performed at a polishing pressure in the range of about 1 psi to about 5 psi and a rotational speed in the range of about 10 rpm to about 100 rpm.

In other embodiments, the insulating layer may have a thickness that is thicker than a depth of the trench and is formed along a profile of the substrate and the trench. The insulating layer may include a low temperature high density plasma (LT-HDP) layer, and the capping dielectric layer includes a high temperature high density plasma (HT-HDP) layer. The method may further comprise forming a nitride layer on the capping dielectric layer. The nitride layer may include SiN, SiON or SiCN. A thickness of the nitride layer may be about 1/120 to about 1/12 smaller than that of the insulating layer. The CMP process can be performed at a polishing pressure in the range of about 1 psi to about 5 psi and a rotational speed in the range of about 10 rpm to about 100 rpm.

In still other embodiments, the insulating layer may have a thickness that is thicker than a depth of the trench and is formed along a profile of the substrate and the trench. The insulating layer may be one selected from the group of a BPSG layer, a PSG layer, a SOG layer, a SACVD layer, and an HARP layer. The capping dielectric layer may include a PTEOS layer or an HDP layer. The method may further comprise forming a nitride layer on the capping dielectric layer. The nitride layer may include SiN, SiON or SiCN. A thickness of the nitride layer is about 1/120 to about 1/12 smaller than that of the insulating layer. The CMP process can be performed at a polishing pressure in the range of 1 psi to 5 psi and a rotational speed in the range of about 10 rpm to about 100 rpm.

In other embodiments, the insulating layer may have a thickness that is thicker than a depth of the trench and is formed along a profile of the substrate and the trench. The insulating layer may be one selected from the group of a BPSG layer, a PSG layer, a SOG layer, a SACVD layer, and an HARP layer. The capping dielectric layer includes SiN, SiON or SiCN. The CMP process may be performed at a polishing pressure in the range of about 1 psi to about 5 psi and a rotational speed in the range of about 10 rpm to about 100 rpm. The forming a trench may comprise recessing a portion of the semiconductor substrate. Or the forming a trench may comprise forming a pattern on the semiconductor substrate.

Although the embodiments of the present invention have been exemplarily described in connection with the accompanying drawings, the embodiments are not limited thereto. It will be apparent to those skilled in the art that various substitution, modifications and changes may be thereto without departing from the scope and spirit of the invention as defined in the claims.

What is claimed is:

1. A method of manufacturing a semiconductor device, comprising:
forming a trench in a semiconductor substrate;
forming an insulating layer filling the trench;
forming a capping dielectric layer on the insulating layer, the capping dielectric layer having a higher density than the insulating layer; and
planarizing the capping dielectric layer and the insulating layer using a chemical mechanical polishing (CMP) process to form a planarized insulating layer.

2. The method of claim 1, wherein a thickness of the insulating layer is greater than a depth of the trench and wherein the insulating layer is formed along a profile of the substrate and the trench.

3. The method of claim 2, wherein the insulating layer includes a low temperature high density plasma (LT-HDP) material and the capping dielectric layer includes a high temperature high density plasma (HT-HDP) material.

4. The method of claim 3, wherein the insulating layer is deposited at a temperature in the range of about 100 degrees centigrade to about 400 degrees centigrade and the capping dielectric layer is deposited at a temperature in the range of about 400 degrees centigrade to about 900 degrees centigrade.

5. The method of claim 4, wherein a thickness of the capping dielectric layer is about 1/20 to about ⅓ of a thickness of the insulating layer.

6. The method of claim 3, further comprising forming a nitride layer on the capping dielectric layer.

7. The method of claim 6, wherein the nitride layer includes SiN, SiON, SiCN, or a combination thereof.

8. The method of claim 7, wherein a thickness of the nitride layer is about 1/120 to about 1/12 of a thickness of the insulating layer.

9. The method of claim 2, wherein the insulating layer includes boron phosphorus silicate glass (BPSG), phosphorus silicate glass (PSG), a spin-on-glass (SOG) material, a semi-atmospheric chemical vapor deposition (SACVD) material, a high aspect ratio process (HARP) material, or a combination thereof.

10. The method of claim 9, wherein the capping dielectric layer includes a plasma tetraethylorthosilicate (PTEOS) material, a high temperature high density plasma (HT-HDP) material, or a combination thereof.

11. The method of claim 10, further comprising forming a nitride layer on the capping dielectric layer.

12. The method of claim 11, wherein the nitride layer includes SiN, SiON, SiCN, or a combination thereof.

13. The method of claim 12, wherein a thickness of the nitride layer is about 1/120 to about 1/12 of a thickness of the insulating layer.

14. The method of claim 9, wherein the capping dielectric layer includes SiN, SiON, SiCN, or a combination thereof.

15. The method of claim 1, wherein the CMP process is performed at a polishing pressure in the range of about 1 psi to about 5 psi and a rotational speed in the range of about 10 rpm to about 100 rpm.

16. The method of claim 1, wherein forming the trench comprises recessing a portion of the semiconductor substrate.

17. The method of claim 1, wherein forming the trench comprises forming a mask pattern on the semiconductor substrate.

18. A method of manufacturing a semiconductor device, comprising:
forming an insulating layer over a substrate, an upper surface of the insulating layer having a step difference between an upper region of the upper surface and a lower region of the upper surface;
forming a capping dielectric layer on the upper surface of the insulating layer, the capping dielectric layer having a higher density than the insulating layer; and
planarizing the capping dielectric layer and the insulating layer using a chemical mechanical polishing (CMP) process to form a planarized insulating layer having a substantially planar upper surface.
